(19) United States
(12) Patent Application Publication
(10) Pub. No.: US 2024/0213890 A1
(43) Pub. Date: Jun. 27, 2024

(54) PIEZOELECTRIC DRIVE DEVICE AND PIEZOELECTRIC DRIVE SYSTEM HAVING SAME

(71) Applicant: Beijing Xiaomi Mobile Software Co.,Ltd., Beijing (CN)

(72) Inventor: Masaru UNO, Tokyo (JP)

(21) Appl. No.: 18/558,027

(22) PCT Filed: Sep. 16, 2021
(86) PCT No.: PCT/CN2021/118797

§ 371 Date: Oct. 30, 2023

(51) Int. Cl. H02N 2/02

(52) U.S. Cl. CPC H02N 2/026

(57) ABSTRACT

A piezoelectric drive device includes: a frame including a deformable part, the deformable part including a first side arm, a second side arm opposite to the first side arm, and a bottom arm connecting the first side arm and the second side arm, the first side arm and the second side arm being inclined towards each other with respect to the bottom arm: a first piezoelectric element and a second piezoelectric element, the first piezoelectric element being arranged between the frame and the first side arm of the deformable part, the second piezoelectric element being arranged between the frame and the second side arm of the deformable part, both the first piezoelectric element and the second piezoelectric element being configured to deform the deformable part: and an actuating part arranged on the bottom arm of the deformable part, and configured to move driven by a deformation of the deformable part.

### CROSS-REFERENCE TO RELATED APPLICATION

The present application is a US national phase application of International Application No. PCT/CN2021/118797, filed on Sep. 16, 2021, the entire content of which is incorporated by reference.

### FIELD

The present disclosure relates to a technical field of piezoelectric drive, and more particularly to a piezoelectric drive device and a piezoelectric drive system having the same.

### BACKGROUND

In the related art, a piezoelectric drive system generally has two types. One is USM type, and the other one is SIDM type. The piezoelectric drive system of the USM type is complicated and expensive, and the generated stroke is very small. On the other hand, the piezoelectric drive system of the SIDM type needs a weight and a shaft, and thus has a complicated structure. Further, the control method of the piezoelectric drive system of the SIDM type is very difficult, as a deformation speed of a piezoelectric element needs to be controlled accurately.

### SUMMARY

As such, it is necessary to propose a piezoelectric drive device and a piezoelectric drive system so as to solve at least one of the above technical problems in the related art.

To this end, embodiments of a first aspect the present disclosure provide a piezoelectric drive device, including: a frame including a deformable part, the deformable part including a first side arm, a second side arm opposite to the first side arm, and a bottom arm connecting the first side arm and the second side arm, the first side arm and the second side arm being inclined towards each other with respect to the bottom arm; a first piezoelectric element and a second piezoelectric element, the first piezoelectric element being arranged between the frame and the first side arm of the deformable part, the second piezoelectric element being arranged between the frame and the second side arm of the deformable part, both the first piezoelectric element and the second piezoelectric element being configured to deform the deformable part: and an actuating part arranged on the bottom arm of the deformable part, and configured to move driven by a deformation of the deformable part.

Embodiments of a second aspect of the present disclosure further provide a piezoelectric drive system, including: a piezoelectric drive device according to any one of the above embodiments: a movable member configured to be fitted with the actuating part of the piezoelectric drive device and to move under the drive of the actuating part: and a retaining spring arranged to the piezoelectric drive device and configured to retain the piezoelectric drive device to press the actuating part against the movable member.

### BRIEF DESCRIPTION OF THE DRAWINGS

The above and/or additional aspects and advantages of the present disclosure will become apparent and easy to understand from descriptions of embodiments in connection with following drawings.

FIG. 1 is a schematic view of a piezoelectric drive device according to an embodiment of the present disclosure.

FIG. 2 is an enlarged view of part A in FIG. 1.

FIG. 3 is a schematic view of a piezoelectric drive system according to an embodiment of the present disclosure.

### DETAILED DESCRIPTION

Embodiments of the present disclosure are described in detail below, and examples of the embodiments are shown in the drawings. Same or similar reference numerals from beginning to end indicate same or similar elements or elements having same or similar functions. The embodiments described below with reference to the attached drawings are exemplary and are only intended to interpret the present disclosure and cannot be understood as a limitation to the present disclosure.

In the description of the present disclosure, it is should be understood that the orientation or position relationships indicated by the terms “central”, “up”, “down”, “front”, “rear”, “vertical”, “horizontal”, “top”, “bottom”, “inner”, “outer”, “axial”, “radial” and “circumferential” are based on the orientation or position relationships shown in the attached drawings, only for the convenience of describing the present disclosure and simplifying the description, instead of indicating or implying that the device or element referred to must have a specific orientation and be constructed and operated in a specific orientation, and thus cannot be understood as a limitation of the present disclosure.

A piezoelectric drive device 100 according to embodiments of the present disclosure will be described with reference to the drawings.

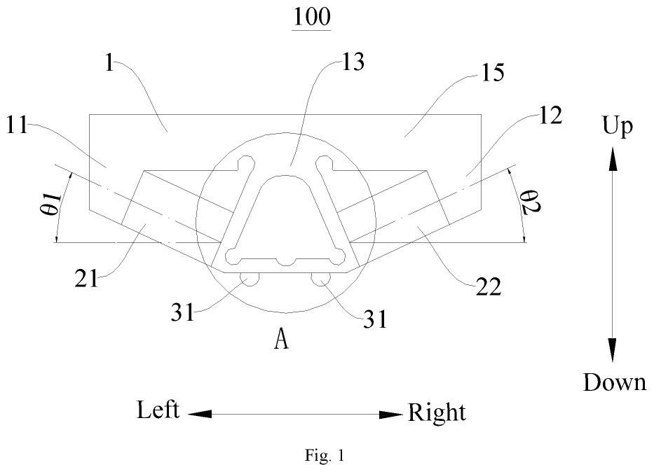

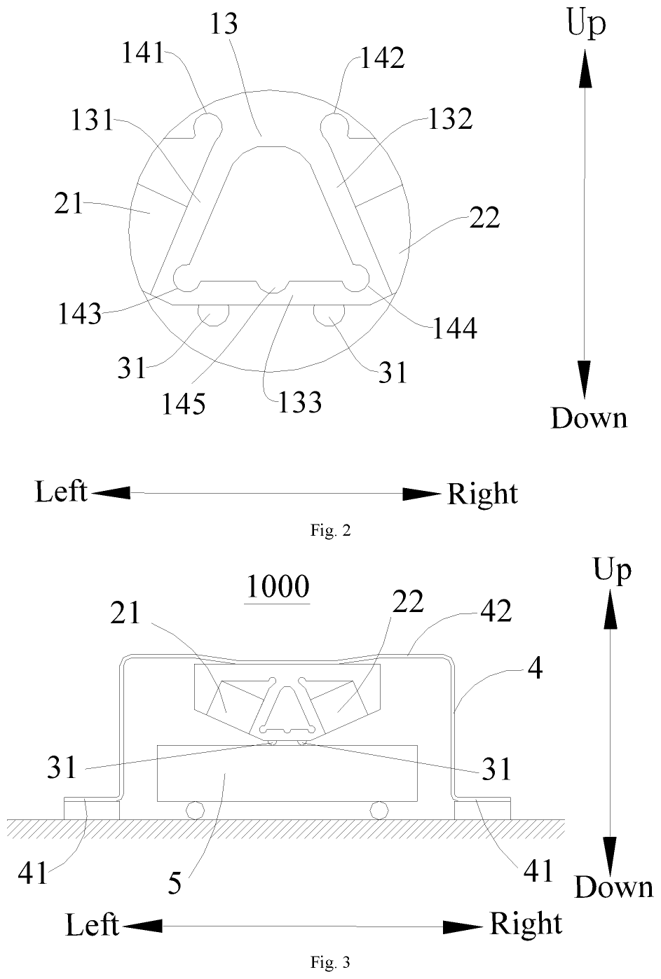

As shown in FIGS. 1 and 2, the piezoelectric drive device 100 includes a frame 1, a first piezoelectric element 21, a second piezoelectric element 22, and an actuating part 31. The frame 1 includes a deformable part 13. The deformable part 13 includes a first side arm 131, a second side arm 132 opposite to the first side arm 131, and a bottom arm 133 connecting the first side arm 131 and the second side arm 132, the first side arm 131 and the second side arm 132 are inclined towards each other with respect to the bottom arm 133. The first piezoelectric element 21 is arranged between the frame 1 and the first side arm 131 of the deformable part 13, the second piezoelectric element 22 is arranged between the frame 1 and the second side arm 132 of the deformable part 13, and both the first piezoelectric element 21 and the second piezoelectric element 22 are configured to deform the deformable part 13. The actuating part 31 is arranged on the bottom arm 133 of the deformable part 13, and configured to move driven by a deformation of the deformable part 13.

In some embodiments of the present disclosure, as shown in FIG. 1, the frame 1 extends horizontally, the first piezoelectric element 21 and the second piezoelectric element 22 are connected to the frame 1 and are spaced apart from each other, the first piezoelectric element 21 is located at a left end of the frame 1, the second piezoelectric element 22 is located at a right end of the frame 1, and the deformable part 13 is located between the first piezoelectric element 21 and the second piezoelectric element 22. Both the first piezoelectric element 21 and the second piezoelectric element 22 are connected to the deformable part 13. The actuating part 31 is arranged on the bottom arm of the deformable part 13.

It should be noted that “left” and “right” are used herein to indicate the orientation in the drawings and intended for easy understanding of the present disclosure, but should not be interpreted as a limitation to the present disclosure.

In the piezoelectric drive device according to the embodiments of the present disclosure, when the first piezoelectric element 21 or the second piezoelectric element 22 is powered on, the first piezoelectric element 21 or the second piezoelectric element 22 expands, and the deformable part 13 will be deformed accordingly, so as to drive the actuating part 31 to move in a corresponding direction, and thus the actuating part 31 can be fitted with a movable member 5 of a piezoelectric drive system 1000 to drive the movable member 5 to move in a desired direction. Further, when the first piezoelectric element 21 or the second piezoelectric element 22 is powered off, the first piezoelectric element 21 or the second piezoelectric element 22 shrinks, and the deformable part 13 will restore to its initial shape, and hence the actuating part 31 will also restore to its initial position without any influence on the movable member 5. As repeated in this manner, the movable member 5 can move continuously in the desired direction.

Consequently, the piezoelectric drive device 100 according to the embodiments of the present disclosure has advantages of a simple structure, a convenient control, and a high drive efficiency.

In some embodiments of the present disclosure, the first piezoelectric element 21 has a first end connected to the frame 1 and a second end connected to the first side arm 131 of the deformable part 13, and is configured to expand or shrink to deform the deformable part 13. The second piezoelectric element 22 has a first end connected to the frame 1 and a second end connected to the second side arm 132 of the deformable part 13, and is configured to expand or shrink to deform the deformable part 13.

Further, the second end of the first piezoelectric element 21 matches with the first side arm 131 of the deformable part 13 in shape and orientation, and the second end of the second piezoelectric element 22 matches with the second side arm 132 of the deformable part 13 in shape and orientation. For example, the second end of the first piezoelectric element 21 has a flat end face parallel with a flat outer surface of the first side arm 131 of the deformable part 13, and the second end of the second piezoelectric element 22 has a flat end face parallel with a flat outer surface of the second side arm 132 of the deformable part 13.

It should be noted that the first side arm 131, the second side arm 132 and the bottom arm 133 of the deformable part 13 form an enclosed cavity, so that “inner” for the deformable part 13 means facing towards the cavity and “outer” for the deformable part 13 means facing away from the cavity herein.

Further, a direction perpendicular to the first side arm 131 of the deformable part 13 intersects with an extending direction of the bottom arm 133 of the deformable part 13 at a first included angle θ₁, and a direction perpendicular to the second side arm 132 of the deformable part 13 intersects with the extending direction of the bottom arm 133 of the deformable part 13 at a second included angle θ₂. As shown in FIG. 1, the extending direction of the bottom arm 133 is horizontal.

In some embodiments of the present disclosure, the first included angle θ₁ between the direction perpendicular to the first side arm 131 of the deformable part 13 and the extending direction of the bottom arm 133 of the deformable part 13 ranges from 24 degrees to 26 degrees, and the second included angle θ₂ between the direction perpendicular to the second side arm 132 of the deformable part 13 and the extending direction of the bottom arm 133 of the deformable part 13 ranges from 24 degrees to 26 degrees.

For example, the first included angle θ₁ may be 24 degrees, 24.5 degrees, 25 degrees, 25.5 degrees or 26 degrees, and the second included angle θ₂ may be 24 degrees, 24.5 degrees, 25 degrees, 25.5 degrees or 26 degrees.

In some embodiments of the present disclosure, the first included angle θ₁ is 25 degrees, and the second included angle θ₂ is 25 degrees.

Since the first included angle θ₁ and the second included angle θ₂ range from 24 degrees to 26 degrees, the movable member 5 of the piezoelectric drive system 1000 can be moved stably and smoothly, and the piezoelectric drive device 100 can achieve the high drive efficiency.

In some embodiments of the present disclosure, as shown in FIG. 1, the deformable part 13 is arranged in middle of the frame 1 and has a symmetrical structure, that is, the first side arm 131 and the second side arm 132 are symmetrical. Accordingly, the first piezoelectric element 21 is symmetrical to the second piezoelectric element 22 with respect to a symmetry axis of the deformable part 13, and the first included angle θ₁ is equal to the second included angle θ₂.

Thus, the whole structure of the piezoelectric drive device 100 is stable and has a high strength, so that the movable member 5 of the piezoelectric drive system 1000 can be driven to move smoothly and stably.

In some embodiments of the present disclosure, the first piezoelectric element 21 and the second piezoelectric element 22 are configured to operate in a d33 mode. Herein, the d33 mode means that a piezoelectric material has a polarization direction and a deformation direction which are the same. In other words, the polarization direction of the first piezoelectric element 21 is consistent with the deformation direction of the first piezoelectric element 21, and both directions are perpendicular to the first side arm 131 of the deformable part 13. Similarly, the polarization direction of the second piezoelectric element 22 is consistent with the deformation direction of the second piezoelectric element 22, and both directions are perpendicular to the second side arm 132 of the deformable part 13.

In some embodiments of the present disclosure, the frame 1 further includes a body 15, a first side portion 11 and a second side portion 12. The first side portion 11 and the second side portion 12 extend from opposite ends of the body 15, respectively. The deformable part 13 extends from middle of the body 15, and is located between the first side portion 11 and the second side portion 12. The deformable part 13 forms a first gap and a second gap, respectively, with the first side portion 11 and the second side portion 12. The first piezoelectric element 21 is arranged in the first gap, and the second piezoelectric element 22 is arranged in the second gap. The first end of the first piezoelectric element 21 is connected with the first side portion 11, and the first end of the second piezoelectric element 22 is connected with the second side portion 12.

In some preferred embodiments of the present disclosure, the body 15, the deformable part 13, the first side portion 11 and the second side portion 12 are integral. Thus, they are easy to manufacture and the structural strength thereof can be improved.

As shown in FIG. 1, the frame 1 includes the body 15 extending horizontally, the first side portion 11 is arranged at a left end of the body 15, the second side portion 12 is arranged at a right end of the body 15, and the deformable part 13 is located between the first side portion 11 and the second side portion 12.

The first piezoelectric element 21 is located between the first side portion 12 and the deformable part 13. The first end of the first piezoelectric element 21 is a left end of the first piezoelectric element 21, and the second end of the first piezoelectric element 21 is a right end of the first piezoelectric element 21. The left end of the first piezoelectric element 21 is connected with the first side portion 11, and the right end of the first piezoelectric element 21 is connected with the first side arm 131 of the deformable part 13.

The second piezoelectric element 22 is located between the second side portion 12 and the deformable part 13. The first end of the second piezoelectric element 22 is a right end of the second piezoelectric element 22, and the second end of the second piezoelectric element 22 is a left end of the second piezoelectric element 22. The left end of the second piezoelectric element 22 is connected with the second side arm 132 of the deformable part 13, and the right end of the second piezoelectric element 22 is connected with the second side portion 12.

In this way, when the first piezoelectric element 21 is powered on to expand along the direction perpendicular to the first side arm 131 of the deformable part 13, the first side portion 11 will restrict the movement of the left end of the first piezoelectric element 21, so that the right end of the first piezoelectric element 21 will press against the deformable part 13 along the direction perpendicular to the first side arm 131 of the deformable part 13, and thus the deformable part 13 is deformed accordingly. Similarly, when the second piezoelectric element 22 is powered on to expand along the direction perpendicular to the second side arm 132 of the deformable part 13, the second side portion 12 will restrict the movement of the right end of the second piezoelectric element 22, so that the left end of the second piezoelectric element 22 will press against the deformable part 13 along the direction perpendicular to the second side arm 132 of the deformable part 13, and thus the deformable part 13 is deformed accordingly.

In some embodiments, as shown in FIG. 1, a left side surface of the first side portion 11 may be vertical, and a right side surface of the first side portion 11 may be parallel to the outer surface of the first side arm 131 of the deformable part 13, so that the first piezoelectric element 21 can apply a stable and even force on the deformable part 13. However, the present disclosure is not limited to this. For example, the right side surface of the first side portion 11 may also be perpendicular to the vertical, as long as the left end of the first piezoelectric element 21 has a flat end face parallel with the right side surface of the first side portion 11.

Similarly, as shown in FIG. 1, a right side surface of the second side portion 12 may be vertical, and a left side surface of the second side portion 12 may be parallel to the outer surface of the second side arm 132 of the deformable part 13, so that the second piezoelectric element 22 can apply a stable and even force on the deformable part 13. However, the present disclosure is not limited to this. For example, the left side surface of the second side portion 12 may also be vertical, as long as the right end of the second piezoelectric element 22 has a flat end face parallel with the left side surface of the second side portion 12.

Further, the first piezoelectric element 21 is adhered to the frame 1 and the deformable part 13, and the second piezoelectric element 22 is adhered to the frame 1 and the deformable part 13. For example, the left end of the first piezoelectric element 21 is adhered to the first side portion 11 by hard glue, the right end of the first piezoelectric element 21 is adhered to the deformable part 13 by hard glue, the right end of the second piezoelectric element 22 is adhered to the second side portion 12 by hard glue, and the left end of the second piezoelectric element 22 is adhered to deformable part 13 by hard glue.

As a result, the connection between the first piezoelectric element 21 and the frame 1, the connection between the first piezoelectric element 21 and the deformable part 13, the connection between the second piezoelectric element 22 and the frame 1, and the connection between the second piezoelectric element 22 and the deformable part 13 are firm and stable, and the hard glue tends not to absorb the expansion of the first piezoelectric element 21 and the second piezoelectric element 22, so that the first piezoelectric element 21 and the second piezoelectric element 22 can press against the deformable part 13 to deform the deformable part 13 reliably and efficiently.

In some embodiments of the present disclosure, the first piezoelectric element 21 includes a plurality of stacked layers and the second piezoelectric element 22 includes a plurality of stacked layers in a direction perpendicular to a paper surface of FIG. 1. The number of the stacked layers of the first piezoelectric element 21 is equal to the number of the stacked layers of the second piezoelectric element 22. Each layer of the first piezoelectric element 21 is adhered to the frame 1 and the deformable part 13, and each layer of the second piezoelectric element 22 is adhered to the frame 1 and the deformable part 13. For example, the number of the stacked layers of the first piezoelectric elements 21 and the number of the stacked layers of the second piezoelectric elements 22 are 15. However, the present disclosure is not limited to this.

In some embodiments of the present disclosure, a first end of the first side arm 131 and a first end of the second side arm 132 are connected to the body 15, and the bottom arm 133 is connected between a second end of the first side arm 131 and a second end of the second side arm 132.

As shown in FIGS. 1 and 2, the first side arm 131 and the second side arm 132 extend obliquely downwards from the body 15, the bottom arm 133 is arranged horizontally, the first end of the first side arm 131 is an upper end of the first side arm 131, the second end of the first side arm 131 is a lower end of the first side arm 131, the first end of the second side arm 132 is an upper end of the second side arm 132, the second end of the second side arm 132 is a lower end of the second side arm 132, the upper end of the first side arm 131 and the upper end of the second side arm 132 are both connected to the body 15, and the lower end of the first side arm 131 is connected to a left end of the bottom arm 133, and the lower end of the second side arm 132 is connected to a right end of the bottom arm 133.

It should be noted that “upper” and “lower” are used herein to indicate the orientation in the drawings and intended for easy understanding of the present disclosure, but should not be interpreted as a limitation to the present disclosure.

Further, the upper ends of the first side arm 131 and the second side arm 132 are spaced apart by a first distance in the extending direction of the bottom arm 133, and the lower ends of the first side arm 131 and the second side arm 132 are spaced apart by a second distance in the extending direction of the bottom arm 133. The first distance is shorter than the second distance to allow the deformable part 13 to have a substantially triangular shape or a substantially “A” shape.

Thus, the first side arm 131 and the second side arm 132 can be deformed almost independently, i.e. without affecting each other, so that a corresponding portion of the bottom arm 133 can be driven to deform and move so as to drive the corresponding actuating part 31 to move accordingly.

In some embodiments of the present disclosure, the upper end of the first side arm 131 and the upper end of the second side arm 132 are connected at one spot. Thus, the first side arm 131, the second side arm 132 and the bottom arm 133 are more like a triangle in shape.

Accordingly, due to the substantially triangular shape or the substantially “A” shape of the deformable part 13, the right end of the first piezoelectric element 21 is lower than the left end of the first piezoelectric element 21, and the left end of the second piezoelectric element 22 is lower than the right end of the second piezoelectric element 22, so that it is convenient for the first piezoelectric element 21 and the second piezoelectric element 22 to act on the deformable part 13.

In some embodiments of the present disclosure, as shown in FIGS. 1 and 2, a first groove 141 is formed in a joint of the first side arm 131 and the body 15, a second groove 142 is formed in a joint of the second side arm 132 and the body 15, a third groove 143 is formed in a joint of the first side arm 131 and the bottom arm 133, and a fourth groove 144 is formed in a joint of the second side arm 132 and the bottom arm 133.

Further, each of the first groove 141, the second groove 142, the third groove 143 and the fourth groove 144 has an arc cross section, which is conducive to elastic deformation and reduces stiffness, thus the local stress concentration can be avoided. It should be noted that these grooves extend in the direction perpendicular to the paper surfaces of FIGS. 1 and 2.

In this way, it is more convenient for the first side arm 131, the second side arm 132 and the bottom arm 133 to deform without failures.

Moreover, a fifth groove 145, which also has an arc cross section, may also be formed in middle of the bottom arm 133, so as to facilitate independent movements of the left and right ends of the bottom arm 133, thus allowing the actuating parts 31 arranged on the left and right ends of the bottom arm 133 respectively to move without any influence on each other.

In some embodiments of the present disclosure, two actuating parts 31 may be provided and arranged on the second end (the lower end) of the first side arm 131 and the second end (the lower end) of the second side arm 132, respectively.

In some other embodiments of the present disclosure, as shown in FIGS. 1 and 2, two actuating parts 31 are provided and arranged on the bottom arm 133 and adjacent to the second end (the lower end) of the first side arm 131 and the second end (the lower end) of the second side arm 132, respectively. That is, the two actuating parts 31 are arranged on the left and right ends of the bottom arm 133, respectively.

In either above case, the two actuating parts 31 are symmetrical with respect to a center line of the bottom arm 133 perpendicular to the extending direction of the bottom arm 133. That is, the center line of the bottom arm 133 is vertical. Further, the first piezoelectric element 21 can drive the movable member 5 of the piezoelectric drive system 1000 to move through the actuating part 31 on the left, and the second piezoelectric element 22 can drive the movable member 5 of the piezoelectric drive system 1000 to move through the actuating part 31 on the right.

Thus, a relatively large movement of the movable member 5 of the piezoelectric drive system 1000 can be achieved by a relatively small deformation of the deformable part 13. That is, a small expansion of the first piezoelectric element 21 or the second piezoelectric element 22 can generate a large movement of the movable member 5 of the piezoelectric drive system 1000. Therefore, a high drive efficiency can be achieved.

In some embodiments of the present disclosure, one actuating part 31 may be provided and arranged on the bottom arm 133. In some embodiments of the present disclosure, the one actuating part 31 is arranged on the center of the surface of the bottom arm 133. Thus, one actuating part 31 can be shared by the first piezoelectric element 21 and the second piezoelectric element 22, so as to achieve the movements of the movable member 5 of the piezoelectric drive system 1000 in opposite directions, which saves the materials and hence reduces the cost.

Moreover, the above embodiments of the arrangement of the actuating part 31 can be combined in any manner without conflict. For example, three actuating parts 31 may be provided, one is arranged on the bottom arm 133, and the other two are arranged on the lower end of the first side arm 131 and the lower end of the second side arm 132, respectively, or are arranged on the bottom arm 133 and adjacent to the lower end of the first side arm 131 and the lower end of the second side arm 133, respectively.

In some embodiments of the present disclosure, the actuating part 31 protrudes from the bottom arm 133 of the deformable part 13 and has a spherical-segment shape.

Thus, a surface of the actuating part 31 is spherical, so as to have a stable contact with the movable member 5 of the piezoelectric drive system 1000, thus ensuring the stable movement of the movable member 5 of the piezoelectric drive system 1000.

Further, the frame 1 is made of ceramic materials, the actuating part 31 is also made of ceramic materials, and the deformable part 13 of the frame 1 and the actuating part 31 are integrally formed. The ceramic materials have a great wear resistance, so that the frame 1 and the actuating part 31 have a long service life. Since the frame 1 and the actuating part 31 are integrally formed, they are easy to process and the connection strength therebetween can be ensured.

Embodiments of the present disclosure further provide a piezoelectric drive system 1000, as shown in FIG. 3. The piezoelectric drive system 1000 includes a piezoelectric drive device 100 according to any one of the above embodiments, a retaining spring 4 and a movable member 5. The movable member 5 is configured to be fitted with the actuating part 31 of the piezoelectric drive device 100 and to move under the drive of the actuating part 31. The retaining spring 4 is arranged to the piezoelectric drive device 100 and configured to retain the piezoelectric drive device 100 to press the actuating part 31 against the movable member 5.

In some embodiments of the present disclosure, the retaining spring 4 has an open rectangle shape to enclose the piezoelectric drive device 100 therein, and includes a flange 41 surrounding its opening, and the flange 41 of the retaining spring 4 is fixed. The retaining spring 4 also has a bottom 42 facing its opening. The bottom 42 of the retaining spring 4 is deformed towards the frame 1 of the piezoelectric drive device 100 and further connected to the frame 1 of the piezoelectric drive device 100 by adhering or caulking. Thus, the retaining spring 4 can apply a pressure to the piezoelectric drive device 100 so as to press the actuating part 31 against the movable member 5. For example, the pressure applied by the retaining spring 4 is about 200 mN.

As shown in FIG. 3, although the movable member 5 is also enclosed in the retaining spring 4, the present disclose is not limited to this. For example, at least part of the movable member 5 may also be arranged outside the retaining spring 4.

In some embodiments of the present disclosure, when an outer peripheral surface of the movable member 5 is flat, the actuating part 31 will drive the movable member 5 to translate: when the outer peripheral surface of the movable member 5 is curved, the actuating part 31 will drive the movable member 5 to rotate.

The working process of the piezoelectric drive system 1000 is briefly described below by taking the first piezoelectric element 21 as an example, in which two actuating parts 31 are arranged on the bottom arm 133 and adjacent to the lower end of the first side arm 13 and the lower end of the second side arm 132 respectively, as shown in FIGS. 1 and 2.

When powered on, the first piezoelectric element 21 expands along the direction perpendicular to the first side arm 131 of the deformable part 13. During the expanding process, the first piezoelectric element 21 presses against the deformable part 13 along the direction perpendicular to the first side arm 131 of the deformable part 13, and forces the first side arm 131 of the deformable part 13 to be deformed rightwards and downwards, then the first side arm 131 drives the bottom arm 133 to be deformed and moved rightwards and downwards, and the bottom arm 133 further drives the actuating part 31 adjacent to the lower end of the first side arm 131 to move rightwards and downwards. The actuating part 31 abuts against the movable member 5 and applies a driving force to the movable member 5. The driving force applied by the actuating part 31 has a rightward component and a downward component. Thus, the movable member 5 is driven to move rightwards. However, in the above expanding process of the first piezoelectric element 21, since the second piezoelectric element 22 is not powered on, the second side arm 132 of the deformable part 13 is not deformed, and thus the other actuating part 31 adjacent to the lower end of the second side arm 132 does not move.

When powered off, the first piezoelectric element 21 shrinks, thereby driving the actuating part 31 to move leftwards and upwards. Since the direction perpendicular to the first side arm 131 of the deformable part 13 intersects with the extending direction of the bottom arm 133 of the deformable part 13 at the first included angle θ₁ ranging from 24 degrees to 26 degrees, the actuating part 31 moving leftwards and upwards cannot apply a driving force to the movable member 5. When viewed microscopically, the actuating part 31 moving leftwards and upwards is even separated from the movable member 5. Thus, the movable member 5 does not move together with the actuating part 31 and still remains in its position. In this way, the piezoelectric drive system 1000 has completed a movement cycle. A periodic pulse signal may be applied to the first piezoelectric element 21, and thus the first piezoelectric element 21 can alternately complete the movements of expanding when powered on and shrinking when powered off. As the movement cycle is repeated, the movable member 5 will move rightwards continuously under the drive of the actuating part 31.

The working process of the second piezoelectric element 22 is substantially the same with that of the first piezoelectric element 21. The difference is that a moving direction of the movable member 5 when the first piezoelectric element 21 operates is opposite to a moving direction of the movable member 5 when the second piezoelectric element 22 operates. For example, the first piezoelectric element 21 drives the movable member 5 to move rightwards, and the second piezoelectric element 22 drives the movable member 5 to move leftwards. In some other embodiments of the present disclosure, the first piezoelectric element 21 may drive the movable element 5 to move clockwise, and the second piezoelectric element 22 may drive the movable element 5 to move counterclockwise. Moreover, in the same time period, only one of the first piezoelectric element 21 and the second piezoelectric element 22 operates. That is, the first piezoelectric element 21 and the second piezoelectric element 22 operate in a mutually exclusive manner.

According to the above embodiments of the present disclosure, the piezoelectric drive system 1000 has advantages of a simple structure, a convenient control, and a high drive efficiency.

In the piezoelectric drive device and the piezoelectric drive system according to the embodiments of the present disclosure, when the first or second piezoelectric element is powered on, the first or second piezoelectric element will expand, and the deformable part will be deformed accordingly, so as to drive the actuating part to move in a corresponding direction, and thus the actuating part can be fitted with the movable member to drive the movable member to move in a desired direction. Further, when the first or second piezoelectric element is powered off, the first or second piezoelectric element will shrink, the deformable part will restore to its initial shape, and hence the actuating part will also restore to its initial position without influence on the movable member. As repeated in this manner, the movable member can move continuously in the desired direction.

Consequently, the piezoelectric drive device and the piezoelectric drive system according to the embodiments of the present disclosure have advantages of a simple structure, a convenient control, and a high drive efficiency.

In the descriptions of the present disclosure, it should be noted that unless specified or limited otherwise, the terms “installed”, “interconnected” and “connected” shall be broadly understood. For example, they may be fixed connections, or detachable connections or integrated connections: they may be mechanical connections or electric connections: they may also be direct connections or indirect connections through intermediate medium, and may also be inner communications of two elements. For those skilled in the art, the specific meaning of the above terms in the present disclosure may be understood according to specific circumstances.

Reference throughout this specification to terms “an embodiment,” “a specific embodiment,” “an example,” means that a particular feature, structure, material, or characteristic described in connection with the embodiment or example is included in at least one embodiment or example of the present disclosure. In this specification, exemplary descriptions of aforesaid terms are not necessarily referring to the same embodiment or example. Moreover, the particular features, structures, materials, or characteristics described may be combined in any suitable manner in one or more embodiments or examples.

Although embodiments of the present disclosure have been illustrated and described above, it should be understood by those skilled in the art that changes, modifications, alternatives, and variations can be made in the embodiments without departing from principles and purposes of the present disclosure. The scope of the present disclosure is defined by the claims and their equivalents.

1. A piezoelectric drive device, comprising:
a frame comprising a deformable part, the deformable part comprising a first side arm, a second side arm opposite to the first side arm, and a bottom arm connecting the first side arm and the second side arm, the first side arm and the second side arm being inclined towards each other with respect to the bottom arm;
a first piezoelectric element and a second piezoelectric element, the first piezoelectric element being arranged between the frame and the first side arm of the deformable part, the second piezoelectric element being arranged between the frame and the second side arm of the deformable part, both the first piezoelectric element and the second piezoelectric element being configured to deform the deformable part; and
an actuating part arranged on the bottom arm of the deformable part, and configured to move driven by a deformation of the deformable part.

2. The piezoelectric drive device according to claim 1, wherein the first piezoelectric element has a first end connected to the frame and a second end connected to the first side arm of the deformable part, and is configured to expand or shrink to deform the deformable part,
the second piezoelectric element has a first end connected to the frame and a second end connected to the second side arm of the deformable part, and is configured to expand or shrink to deform the deformable part.

3. The piezoelectric drive device according to claim 2, wherein the second end of the first piezoelectric element matches with the first side arm of the deformable part in shape and orientation, and the second end of the second piezoelectric element matches with the second side arm of the deformable part in shape and orientation,
a direction perpendicular to the first side arm of the deformable part intersects with an extending direction of the bottom arm of the deformable part at a first included angle, and a direction perpendicular to the second side arm of the deformable part intersects with the extending direction of the bottom arm of the deformable part at a second included angle.

4. The piezoelectric drive device according to claim 2, wherein the frame further comprises:
a body; and
a first side portion and a second side portion extending from opposite ends of the body respectively,
wherein the deformable part extends from middle of the body, and is located between the first side portion and the second side portion, the deformable part forms a first gap and a second gap, respectively, with the first side portion and the second side portion, the first piezoelectric element is arranged in the first gap, the second piezoelectric element is arranged in the second gap, the first end of the first piezoelectric element is connected with the first side portion, and the first end of the second piezoelectric element is connected with the second side portion.

5. The piezoelectric drive device according to claim 1, wherein a first end of the first side arm and a first end of the second side arm are connected to the body, and the bottom arm is connected between a second end of the first side arm and a second end of the second side arm,
the first end of the first side arm and the first end of the second side arm are spaced apart by a first distance in an extending direction of the bottom arm, and the second end of the first side arm and the second end of the second side arm are spaced apart by a second distance in the extending direction of the bottom arm,
the first distance is shorter than the second distance to allow the deformable part to have a substantially triangular shape or a substantially “A” shape.

6. The piezoelectric drive device according to claim 5, wherein a first groove is formed in a joint of the first side arm and the body, a second groove is formed in a joint of the second side arm and the body, a third groove is formed in a joint of the first side arm and the bottom arm, and a fourth groove is formed in a joint of the second side arm and the bottom arm.

7. The piezoelectric drive device according to claim 5, wherein two actuating parts are provided and arranged on the second end of the first side arm and the second end of the second side arm, respectively; or
two actuating parts are provided and arranged on the bottom arm and adjacent to the second end of the first side arm and the second end of the second side arm, respectively.

8. The piezoelectric drive device according to claim 7, wherein the two actuating parts are symmetrical with respect to a center line of the bottom arm perpendicular to the extending direction of the bottom arm.

9. The piezoelectric drive device according to claim 1, wherein one actuating part is provided and arranged on the bottom arm.

10. The piezoelectric drive device according to claim 1, wherein the actuating part protrudes from the bottom arm of the deformable part and has a spherical-segment shape.

11. The piezoelectric drive device according to claim 1, wherein the first piezoelectric element and the second piezoelectric element are configured to operate in a d33 mode.

12. The piezoelectric drive device according to claim 1, wherein a first included angle between a direction perpendicular to the first side arm of the deformable part and an extending direction of the bottom arm of the deformable part ranges from 24 degrees to 26 degrees, and a second included angle between a direction perpendicular to the second side arm of the deformable part and the extending direction of the bottom arm of the deformable part ranges from 24 degrees to 26 degrees.

13. The piezoelectric drive device according to claim 1, wherein the deformable part is arranged in middle of the frame and has a symmetrical structure, in which the first side arm and the second side arm are symmetrical with each other,
the first piezoelectric element is symmetrical to the second piezoelectric element with respect to a symmetry axis of the deformable part, and a first included angle between a direction perpendicular to the first side arm of the deformable part and an extending direction of the bottom arm of the deformable part is equal to a second included angle between a direction perpendicular to the second side arm of the deformable part and the extending direction of the bottom arm of the deformable part.

14. The piezoelectric drive device according to claim 1, wherein the frame is made of ceramic materials, the actuating part is made of ceramic materials, and the deformable part of the frame and the actuating part are integrally formed.

15. The piezoelectric drive device according to claim 1, wherein the first piezoelectric element is adhered to the frame and the deformable part, and the second piezoelectric element is adhered to the frame and the deformable part.

16. A piezoelectric drive system, comprising:
a piezoelectric drive device, comprising:
a frame comprising a deformable part, the deformable part comprising a first side arm, a second side arm opposite to the first side arm, and a bottom arm connecting the first side arm and the second side arm, the first side arm and the second side arm being inclined towards each other with respect to the bottom arm;
a first piezoelectric element and a second piezoelectric element, the first piezoelectric element being arranged between the frame and the first side arm of the deformable part, the second piezoelectric element being arranged between the frame and the second side arm of the deformable part, both the first piezoelectric element and the second piezoelectric element being configured to deform the deformable part; and
an actuating part arranged on the bottom arm of the deformable part, and configured to move driven by a deformation of the deformable part;
a movable member configured to be fitted with the actuating part of the piezoelectric drive device and to move under the drive of the actuating part; and
a retaining spring arranged to the piezoelectric drive device and configured to retain the piezoelectric drive device to press the actuating part against the movable member.

17. The piezoelectric drive system according to claim 16, wherein the first piezoelectric element has a first end connected to the frame and a second end connected to the first side arm of the deformable part, and is configured to expand or shrink to deform the deformable part,
the second piezoelectric element has a first end connected to the frame and a second end connected to the second side arm of the deformable part, and is configured to expand or shrink to deform the deformable part.

18. The piezoelectric drive system according to claim 17, wherein the second end of the first piezoelectric element matches with the first side arm of the deformable part in shape and orientation, and the second end of the second piezoelectric element matches with the second side arm of the deformable part in shape and orientation,
a direction perpendicular to the first side arm of the deformable part intersects with an extending direction of the bottom arm of the deformable part at a first included angle, and a direction perpendicular to the second side arm of the deformable part intersects with the extending direction of the bottom arm of the deformable part at a second included angle.

19. The piezoelectric drive system according to claim 17, wherein the frame further comprises:
a body; and
a first side portion and a second side portion extending from opposite ends of the body respectively,
wherein the deformable part extends from middle of the body, and is located between the first side portion and the second side portion, the deformable part forms a first gap and a second gap, respectively, with the first side portion and the second side portion, the first piezoelectric element is arranged in the first gap, the second piezoelectric element is arranged in the second gap, the first end of the first piezoelectric element is connected with the first side portion, and the first end of the second piezoelectric element is connected with the second side portion.

20. The piezoelectric drive system according to claim 16, wherein a first end of the first side arm and a first end of the second side arm are connected to the body, and the bottom arm is connected between a second end of the first side arm and a second end of the second side arm,
the first end of the first side arm and the first end of the second side arm are spaced apart by a first distance in an extending direction of the bottom arm, and the second end of the first side arm and the second end of the second side arm are spaced apart by a second distance in the extending direction of the bottom arm,
the first distance is shorter than the second distance to allow the deformable part to have a substantially triangular shape or a substantially “A” shape.
